(19) United States
(12) Patent Application Publication
(10) Pub. No.: US 2026/0231408 A1
(43) Pub. Date: Aug. 6, 2026

(54) FLASH MEMORY DEVICE AND METHOD FOR FORMING THE SAME

(71) Applicant: Winbond Electronics Corp., Taichung City (TW)

(72) Inventors: Yung-Han CHIU, Taichung City (TW); Yu-Chi LIN, Taichung City (TW); Shu-Ming LI, Kaohsiung City (TW); Han-Huei HSU, Changhua County (TW); Jeng-Yang LIN, Taichung City (TW)

(21) Appl. No.: 19/454,986

(22) Filed: Jan. 21, 2026

(30) Foreign Application Priority Data
Feb. 5, 2025 (TW) 114104060

(51) Int. Cl. H10B 41/30; H10W 10/00; H10W 10/17

(52) U.S. Cl. CPC H10B 41/30; H10W 10/014; H10W 10/17

(57) ABSTRACT

A flash memory device and a method for forming the same are provided. The flash memory device includes a substrate, a semiconductor stack structure and isolation features. The semiconductor stack structure is disposed on the substrate and includes first and second floating gates. The isolation features protrude from the substrate, so that the semiconductor stack structure is sandwiched between the isolation features. Each of the isolation features includes a first dielectric filling layer, a second dielectric liner and a third dielectric filling layer. The first and third dielectric filling layers are located at lower and upper portions of the isolation feature. The second dielectric liner is sandwiched between the first and third dielectric filling layers. The first and third dielectric filling layers are formed of a first material. The second dielectric liner is formed of a second material that is different from the first material.

### CROSS REFERENCE TO RELATED APPLICATIONS

This application claims priority of Taiwan patent application No. 114104060, filed on Feb. 5, 2025, the entirety of which is incorporated by reference herein.

### TECHNICAL FIELD

The present disclosure is related to a flash memory device and a method for forming a flash memory device, and in particular, it is related to an isolation feature of a NAND type flash memory device and a method for forming an isolation feature of a NAND type flash memory device.

### BACKGROUND

The current trend in semiconductor manufacturing technology continues to be the miniaturization of component sizes. However, this gives rise to many challenges in the effort to increase the density of components in semiconductors and improve their overall performance. Therefore, it is urgent to overcome the various problems that arise.

### BRIEF SUMMARY

An embodiment of the present disclosure provides a flash memory device. The flash memory device includes a substrate, a semiconductor stack structure and isolation features. The semiconductor stack structure is disposed on the substrate. The semiconductor stack structure includes a first floating gate and a second floating gate. The second floating gate is disposed on the first floating gate. The isolation features are disposed in the substrate and protrude from the substrate, so that the semiconductor stack structure is sandwiched between the isolation features. Each of the isolation features includes a first dielectric filling layer, a second dielectric liner and a third dielectric filling layer. The first dielectric filling layer is located at a lower portion of the isolation feature. The second dielectric liner conformally covers the first dielectric filling layer. The third dielectric filling layer is located on an upper portion of the isolation feature, so that the second dielectric liner is sandwiched between the first dielectric filling layer and the third dielectric filling layer. The first dielectric filling layer and the third dielectric filling layer are formed of a first material. The second dielectric liner is formed of a second material. The second material is different from the first material. A first top surface of each of the isolation features includes a third top surface of the third dielectric filling layer and a second top surface of the second dielectric liner.

An embodiment of the present disclosure provides a method for forming a flash memory device. The method includes providing a substrate. The method further includes forming a semiconductor stack structure and isolation features on the substrate. The isolation features protrude from the substrate, so that the semiconductor stack structure is sandwiched between the isolation features. The semiconductor stack structure includes a first floating gate and a second floating gate. The second floating gate is disposed on the first floating gate. The formation of each isolation feature includes forming a first dielectric filling layer in the substrate adjacent to the semiconductor stack structure. A first top surface of the first dielectric filling layer is recessed from a second top surface of the semiconductor stack structure. The formation of each isolation feature further includes conformally forming a second dielectric liner material layer on the semiconductor stack structure and the first top surface of the first dielectric filling layer. The formation of each isolation feature further includes forming a third dielectric filling material layer on the second dielectric liner material layer. The formation of each isolation feature further includes removing a portion of the second dielectric liner material layer and a portion of the third dielectric filling material layer to expose second side surfaces of the second floating gate, thereby forming a second dielectric liner and a third dielectric filling layer of each of the isolation features. A first top surface of each of the isolation features includes a top surface of the third dielectric filling layer and a top surface of the second dielectric liner. The first dielectric filling layer and the third dielectric filling material layer are formed of a first material, and the second dielectric liner material layer is formed of a second material that is different from the first material.

### BRIEF DESCRIPTION OF THE DRAWINGS

The present invention can be more fully understood by reading the subsequent detailed description and examples with references made to the accompanying drawings, wherein:

FIGS. 1A to 8A and FIGS. 1B to 8B are schematic partial cross-sectional views of intermediate stages of a method for forming a flash memory device in accordance with some embodiments of the disclosure.

### DETAILED DESCRIPTION

The following description is made for the purpose of illustrating the general principles of the invention and should not be taken in a limiting sense. The scope of the invention is best determined by reference to the appended claims.

In the conventional flash memory manufacturing process, recesses in the isolation features in the array region of the flash memory device have different depths in locations having different pattern densities, causing the word line (WL) disturb problem, affecting the electrical performance and reliability of the final flash memory device. Therefore, a flash memory and a method for forming the same are needed to solve the abovementioned problems.

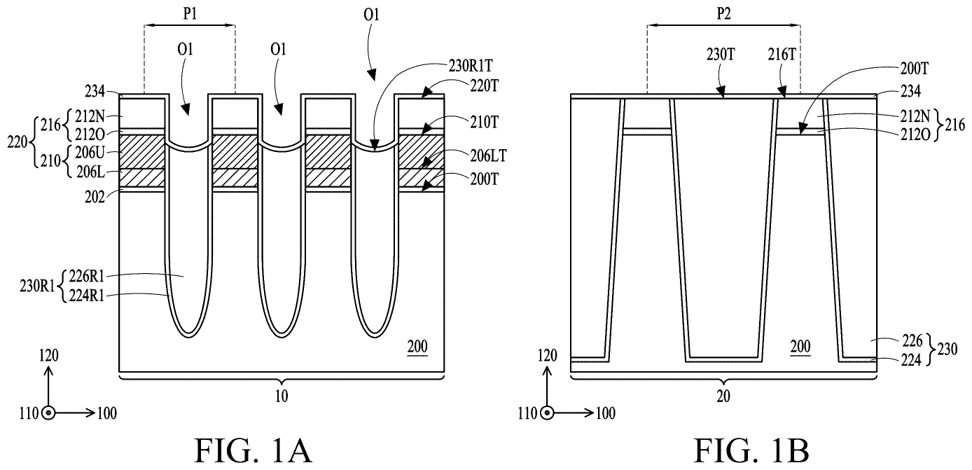

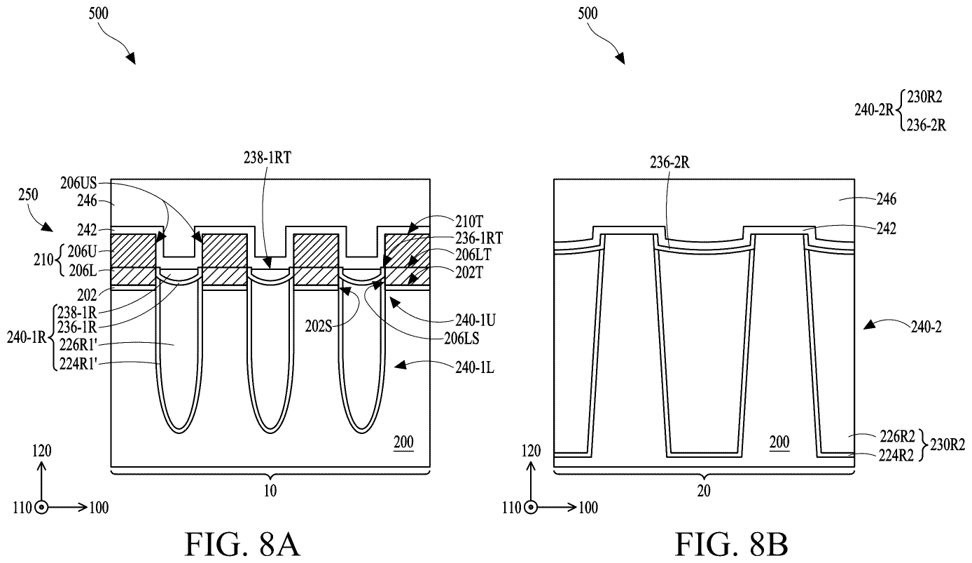

FIGS. 1A to 8A and FIGS. 1B to 8B are schematic cross-sectional views of intermediate stages of a method for forming a flash memory device 500 in the locations 10 and 20 in an array region having different pattern densities. In some embodiments, the location 10 is a position having a higher pattern density, and the location 20 is a position having a lower pattern density. For example, the location 10 may be a location where semiconductor stack structures 250 (FIG. 8A) respectively having a floating gate and a control gate are disposed. In addition, the location 20 may be a location between adjacent semiconductor stack structures 250. In FIGS. 1A, 1B and subsequent figures, directions 100, 110 and 120 are shown as x, y and z directions respectively. The directions 100 and 110 are directions substantially parallel to the top surface 200T of the substrate 200. In addition, the directions 100 and 110 are respectively the word line (width) direction and the bit line (length) direction of the flash memory device 500. The direction 120 is a direction substantially perpendicular to the top surface 200T of the substrate 200 (also referred to as the longitudinal direction 120).

As shown in FIGS. 1A and 1B, a substrate 200 is provided. The substrate 200 may include an elemental semiconductor substrate, such as a silicon substrate or a germanium substrate; or a compound semiconductor substrate, such as a silicon carbide substrate, a gallium arsenide substrate, a gallium phosphide substrate, an indium phosphide substrate, an indium arsenide substrate and/or an indium antimonide substrate; or an alloy semiconductor, such as SiGe, GaAsP, AlInAs, AlGaAs, GaInAs, GaInP, GaInAsP, and/or a combination thereof. In one embodiment, the substrate 200 may be a silicon-on-insulator substrate. In this embodiment, the substrate 200 is a silicon substrate.

Next, a plurality of tunneling dielectric layers 202, a plurality of semiconductor stack structures 220 and a plurality of isolation structures 230R1 are formed on the substrate 200 in the location 10 where the floating gates are disposed. In addition, a plurality of mask patterns 216 and a plurality of isolation structures 230 are formed on the substrate 200 in the location 20 where the floating gates are not disposed. The method for forming the semiconductor stack structure 220 may include forming a tunneling dielectric material layer (not shown) and a semiconductor stack layer (not shown) including a mask material layer on the substrate 200 in the location 10, and forming a mask material layer on the substrate 200 in the location 20. Next, an etching process is performed using a patterned mask to etch the tunneling dielectric material layer and the semiconductor stacking layer in the location 10 and the mask material layer in the location 20 to form a plurality of trenches (not shown) in the substrate 200. The semiconductor stacking layer in the location 10 is divided into a plurality of tunneling dielectric layers 202 and a plurality of semiconductor stack structures 220 by the trenches. The mask material layer in the location 20 is divided into a plurality of mask patterns 216 by the trenches. In some embodiments, the etching process for forming the semiconductor stack structure 220 (or the mask pattern 216) may include an anisotropic etching process, such as a dry etching process.

The tunneling dielectric layer 202 is disposed on the substrate 200 and sandwiched between the substrate 200 and the semiconductor stack structure 220. In some embodiments, the tunneling dielectric layer 202 may include oxide, nitride, oxynitride, or a combination thereof. For example, the tunneling dielectric layer 202 may be silicon oxide, silicon nitride, silicon oxynitride, a high-k material, or a combination thereof. In this embodiment, the tunneling dielectric layer 202 is, for example, silicon oxide. In some embodiments, the tunneling dielectric layer 202 may be formed by a deposition process or a thermal oxidation process.

The semiconductor stack structures 220 and the isolation structures 230R1 in the location 10 are alternately arranged in the direction 100. The mask patterns 216 and the isolation structures 230 in the location 20 are alternately arranged in the direction 100. Furthermore, the isolation structures 230 and 230R1 protrude from the substrate, so that the semiconductor stack structure 220 in the location 10 is sandwiched between the isolation structures 230R1 in the direction 100, and the mask pattern 216 in the location 20 is sandwiched between the isolation structures 230 in the direction 100.

As shown in FIG. 1A, the semiconductor stack structure 220 includes a floating gate 210 and a mask pattern 216 in sequence from bottom to top. In some embodiments, the floating gate 210 includes a first floating gate 206L disposed on the tunneling dielectric layer and a second floating gate 206U disposed on the first floating gate 206L. The first floating gate 206L may be undoped, and the second floating gate 206U may be doped with dopants. In some embodiments, the floating gate 210 may include a conductive material. For example, the floating gate 210 may include doped or undoped polysilicon, amorphous silicon, metal, metal nitride, conductive metal oxide, or a combination thereof. For example, the first floating gate 206L may be undoped polysilicon, and the second floating gate 206U may be doped polysilicon. In some embodiments, the dopant may include N-type or P-type dopants, such as nitrogen, arsenic, phosphorus, antimony ions, or boron, aluminum, gallium, indium, boron trifluoride (BF³⁺) ions. In some embodiments of the disclosure, the dopant is P-type, so as to increase the number of electrons controlled by the subsequent control gate. In some embodiments, the floating gate 210 may be formed using a deposition process.

In some embodiments, each of the mask patterns 216 includes an oxide layer 212O and a nitride layer 212N. The mask patterns 216 may be used as an etching mask for the etching process of forming the tunneling dielectric layer 202 and the floating gate 210 to protect the underlying film layers from being affected by the etching process.

In some embodiments, the oxide layer 212O includes an oxide, such as tetraethyl orthosilicate (TEOS) oxide. In some embodiments, the nitride layer 212N includes a nitride, such as silicon nitride (SiN) or silicon oxynitride (SiON). As shown in FIGS. 1A and 1B, the mask patterns 216 in the locations 10 and 20 may have the same structure.

After forming the semiconductor stack structures 220 in the location 10 and the mask patterns 216 in the location 20, the isolation structures 230R1, 230 are formed in the locations 10, 20 of the substrate 200. The formation method of the isolation structures 230R1 and 230 may include performing a deposition process to deposit a dielectric liner material layer (not shown) and a dielectric filling material layer (not shown) in the trenches between the adjacent semiconductor stack structures 220 in the location 10 and between the adjacent mask patterns 216 in the location 20. Next, a removal process is performed to remove the excess dielectric liner material layer and the dielectric filling material layer on the top surfaces of the semiconductor stack structures 220 in the location 10 and the top surfaces of the mask patterns 216 in the location 20, so as to form a plurality of isolation structures 230 in the locations 10 and 20. Next, a patterning process may be performed to recess the isolation structures 230 in the location 10 to form isolation structures 230R1 in the location 10 and openings O1 between the semiconductor stack structures 220. In some embodiments, the patterning process for forming the isolation structures 230R1, 230 may include an anisotropic etching process, such as a dry etching process. The removal process may include a planarization process or the aforementioned etching process. The aforementioned planarization process may include chemical mechanical polishing (CMP).

The isolation structures 230R1 are formed in the substrate 200 adjacent to the semiconductor stack structures 220 to define active regions (located on opposite sides of the isolation structures 230R1) in the location 10. Furthermore, the isolation structures 230 are formed in the substrate 200 adjacent to the mask patterns 216 to define active regions (located on opposite sides of the isolation structures 230) in the location 20. In some embodiments, each of the isolation structures 230, 230R1 may be a single-layer structure or a multi-layer structure. In some embodiments, the isolation structures 230 and 230R1 are multi-layer structures. For example, each of the isolation structures 230R1 includes a dielectric liner 224R1 and a dielectric filling layer 226R1 disposed on the dielectric liner 224R1, In addition, each of the isolation structures 230 includes a dielectric liner 224 and a dielectric filling layer 226 disposed on the dielectric liner 224.

As shown in FIG. 1A, the dielectric liners 224R1 are formed in the substrate 200 adjacent to the semiconductor stack structures 220. The dielectric liners 224R1 surround the dielectric filling layers 226R1 and are adjacent to opposite side surfaces of the tunneling dielectric layer 202 and the floating gate 210. The top surface 230R1T of the isolation structure 230R1 is recessed from the top surface 220T of the semiconductor stack structure 220. For example, the top surface 230R1T of the isolation structure 230R1 (including the top surface of the dielectric filling layer 226R1) is a concave arc surface. In some embodiments, the lowest point of the concave arc surface (the top surface 230R1T) is located above the top surface 206LT of the first floating gate 206L and below the top surface 210T of the floating gate 210 (i.e., the top surface of the second floating gate 206U).

As shown in FIG. 1B, the dielectric liners 224 are formed in the substrate 200 adjacent to the mask patterns 216. The dielectric liners 224 surround the dielectric filling layers 226 and are adjacent to opposite side surfaces of the mask patterns 216. The top surface 230T of the isolation structure 230 is aligned with the top surface 216T of the mask pattern 216.

In some embodiments, the isolation structure 230, 230R1 may include a dielectric material, such as silicon oxide, silicon nitride, silicon oxynitride, phosphosilicate glass, borophosphosilicate glass, fluorinated silicate glass, undoped silica glass, organosilicate glass, SiOₓC_{y}, spin-on glass, tetraethyl orthosilicate, a low-k dielectric material, or a combination thereof. In some embodiments, the dielectric liner 224 and the dielectric filling layer 226 of the isolation structure 230 and the dielectric liner 224R1 and the dielectric filling layer 226R1 of the isolation structure 230R1 include the same material, such as silicon oxide.

It should be noted that the pattern density in the location 10 is higher than that in the location 20. The pitch P2 of the mask patterns 216 in the location 20 is greater than the pitch P1 of the semiconductor stack structures 220 in the location 10. Therefore, the shapes of the isolation structures 230 and 230R1 are slightly different. For example, as shown in FIG. 1A, the isolation structure 230R1 in the location 10 has a larger aspect ratio, resulting in a water drop-shaped profile. In contrast, as shown in FIG. 1B, the isolation structure 230 in the location 20 has a smaller aspect ratio, resulting in a trapezoidal profile (i.e., wider at the bottom).

Next, a deposition process such as atomic layer deposition (ALD) may be performed to conformally form a dielectric spacer layer 234 on the semiconductor stack structures 220, the mask patterns 216, and the isolation structures 230R1 and 230. The dielectric spacer layer 234 covers the top surfaces 220T and portions of the side surfaces of the semiconductor stack structures 220, the top surfaces 216T of the mask patterns 216, the top surfaces 230R1T of the isolation structures 230R1, and the top surfaces 230T of the isolation structures 230.

In some embodiments, the dielectric spacer layer 234 includes the same material as the dielectric liner 224 and the dielectric filling layer 226 of the isolation structure 230 and the dielectric liner 224R1 and the dielectric filling layer 226R1 of the isolation structure 230R1, such as silicon oxide.

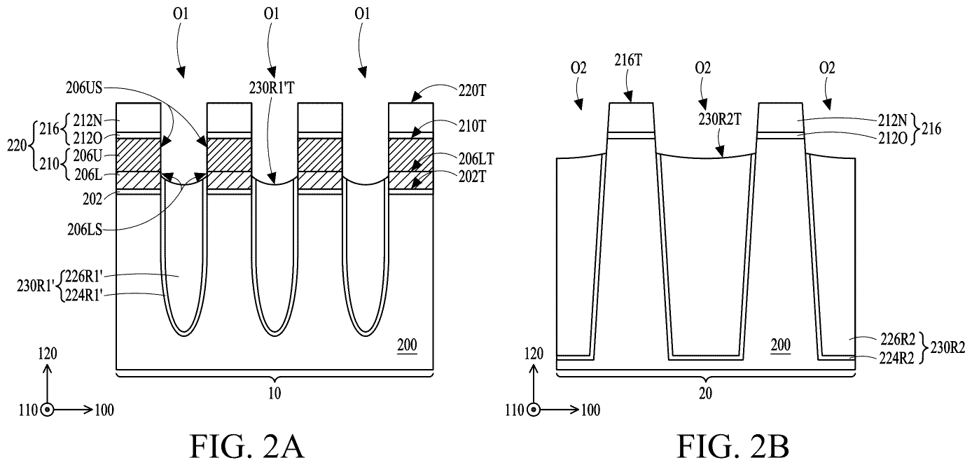

Next, as shown in FIG. 2A and FIG. 2B, an etching process such as reactive ion etching (RIE) may be performed to recess the isolation structure 230R1 and the isolation structure 230 in the location 10 and the location 20 and remove the dielectric spacer layer 234. The etching process recesses the dielectric filling layers 226R1 and the dielectric liners 224R1 from the openings O1 in the location 10, so that the opposite side surfaces 206US of the second floating gates 206U (or completely exposes the opposite side surfaces 206US of the second floating gates 206U are completely exposed). In the location 10, the recess etched isolation structure (including the dielectric filling layer and the dielectric liner) is labeled as an isolation structure 230R1′ (including ae dielectric filling layer 226R1′ and a dielectric liner 224R1′).

In addition, the etching process recesses the dielectric filling layers 226 and the dielectric liners 224 in the location 20 and forms openings O2 between the mask patterns 216. In the location 20, the recess etched isolation structure (including the dielectric filling layer and the dielectric liner) is labeled as the isolation structure 230R2 (including a dielectric filling layer 226R2 and a dielectric liner 224R2).

In some embodiments, the top surfaces 230R1′T of the recess etched isolation structures 230R1′ are concave arc surfaces. The concave arc surfaces may intersect with the opposite side surfaces 206LS of the first floating gates 206L, and may partially expose the opposite side surfaces 206LS of the first floating gates 206L. Furthermore, the lowest point of each of the concave arc surfaces is located above the top surface 202T of the tunneling dielectric layer 202 and below the top surface of the first floating gate 206L. In some embodiments, the recess etched dielectric filling layers 226R1′ (or the isolation structure 230R1′) may partially cover the opposite side surfaces 206LS of the first floating gate 206L.

Since the pitch P2 of the mask patterns 216 in the location 20 is greater than the pitch P1 of the semiconductor stack structures 220 in the location 10, the openings O2 formed in the isolation structure 230R2 are shallower than the openings O1.

Next, a cleaning process is performed on the intermediate structure for use in the manufacture of the flash memory device 500. In some embodiments, the isolation structures 230R1′ and 230R2 may be further subjected to an annealing process to further strengthen the isolation structures 230R1′ and 230R2.

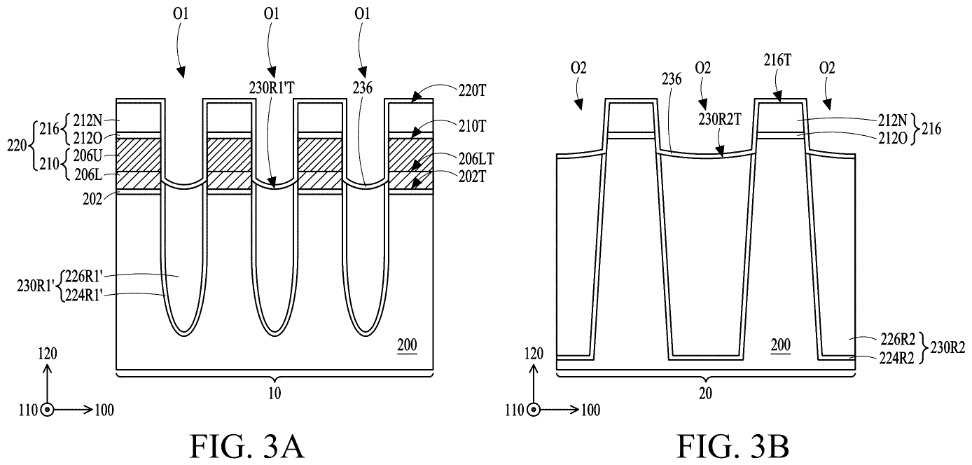

Next, as shown in FIGS. 3A and 3B, a deposition process such as atomic layer deposition (ALD) may be performed to conformally form a dielectric liner material layer 236 on the top surfaces 220T of the semiconductor stack structures 220, the top surfaces 216T of the mask patterns 216, the top surfaces 230R1′T of the isolation structures 230R1′, and the top surfaces 230R2T of the isolation structures 230R2 in the locations 10 and 20.

The dielectric liner material layer 236 covers the dielectric liner layers 224R1′, 224R2 and the dielectric filling layers 226R1′, 226R2, and is adjacent to the opposite side surfaces 206US of the second floating gates 206U. Furthermore, in the location 10, the dielectric liner 224R1′ and the dielectric liner material layer 236 are adjacent to different portions of the side surface 206LS of the first floating gate 206L. It should be noted that the dielectric liner material layer 236 does not completely fill the openings O1 and O2.

In some embodiments, the dielectric liner material layer 236 includes a nitride, such as silicon nitride (SiN) or silicon oxynitride (SiON). In some embodiments, the material of the dielectric liner material layer 236 is different from the material of the dielectric liner 224R1′ and the dielectric filling layer 226R1′ of the isolation structure 230R1′ and the material of the dielectric liner 224R2 and the dielectric filling layer 226R2 of the isolation structure 230R2. The material of the dielectric liner material layer 236 may be the same as the material of the nitride layer 212N. For example, the dielectric liner 224R1′ and the dielectric filling layer 226R1′ of the isolation structure 230R1′ and the dielectric liner 224R2 and the dielectric filling layer 226R2 of the isolation structure 230R2 are formed of silicon oxide, and the dielectric liner material layer 236 and the nitride layer 212N are formed of silicon nitride. In addition, the interface between the dielectric liner material layer 236 and the nitride layer 212N formed of the same material is not obvious.

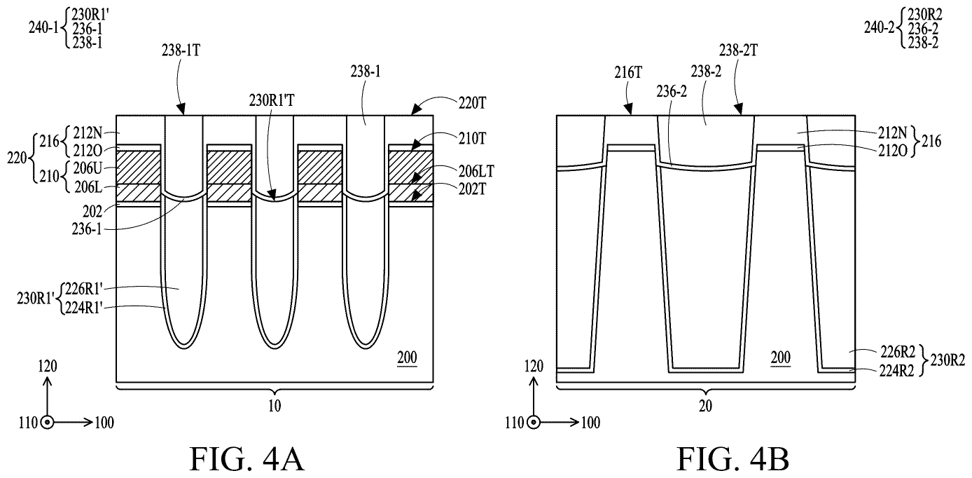

Next, as shown in FIG. 4A and FIG. 4B, a deposition process such as spin-on-glass (SOG) may be performed to entirely form a dielectric filling material layer (not shown) on the dielectric liner material layer 236. The dielectric filling material layer completely fills the openings O1 and O2 and covers the semiconductor stack structures 220, the mask patterns 216, the isolation structures 230R1′ and 230R2, and the dielectric liner material layer 236.

Next, a planarization process such as chemical mechanical polishing (CMP) may be performed to remove portions of the dielectric filling material layer and the dielectric liner material layer 236 on the top surfaces 220T of the semiconductor stack structures 220 and the top surfaces 216T of the mask patterns 216, until the top surfaces 220T of the semiconductor stack structures 220 and the top surfaces 216T of the mask patterns 216 are exposed, so as to form a dielectric liner material layer 236-1 and a dielectric filling material layer 238-1 in the opening O1 between the semiconductor stack structures 220, and to form a dielectric liner material layer 236-2 and a dielectric filling material layer 238-2 in the opening O2 between the mask patterns 216. After performing the planarization process, the top surface 220T of the semiconductor stack structure 220 and the top surface 216T of the mask pattern 216 may be flush with the top surface 238-1T of the dielectric filling material layer 238-1 and the top surface 238-2T of the dielectric filling material layer 238-2.

After performing the aforementioned process, a plurality of isolation features 240-1 may be formed in the location 10, and a plurality of isolation features 240-2 may be formed in the location 20. The isolation feature 240-1 includes an isolation structure 230R1′, a dielectric liner material layer 236-1 and a dielectric filling material layer 238-1, from bottom to top. The isolation feature 240-2 includes an isolation structure 230R2, a dielectric liner material layer 236-2, and a dielectric filling material layer 238-2, from bottom to top.

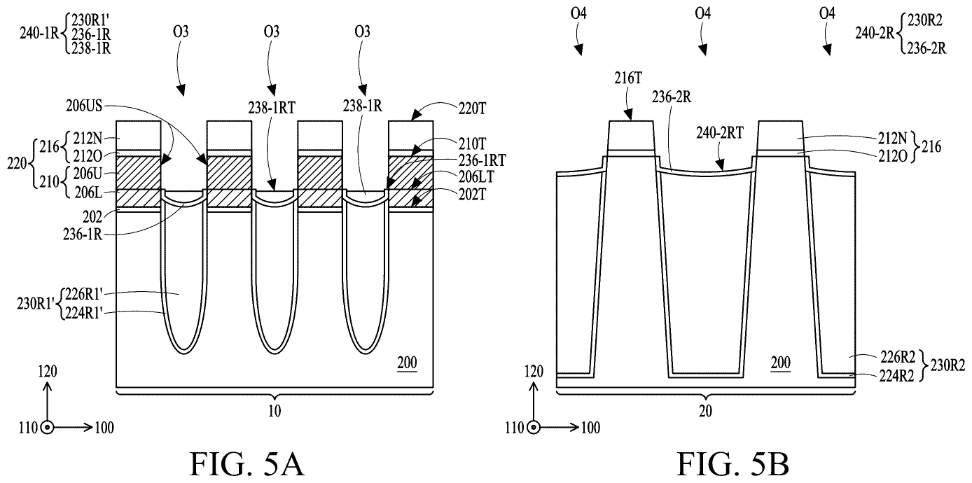

Next, as shown in FIGS. 5A and 5B, an etching process such as dry etching may be performed to remove a portion of the dielectric liner material layer 236-1 and a portion of the dielectric filling material layer 238-1 of the isolation feature 240-1 in the location 10 to expose the opposite side surfaces 206US of the second floating gate 206U, thereby forming an isolation feature 240-1R including an isolation structure 230R1′, a dielectric liner 236-1R and a dielectric filling layer 238-1R. Furthermore, a portion of the dielectric liner material layer 236-2 and the entire dielectric filling material layer 238-2 of the isolation feature 240-2 are removed in the location 20 to form an isolation feature 240-2R including an isolation structure 230R2 and a dielectric liner layer 236-2R. Since the dielectric liner material layers 236-1, 236-2 and the dielectric filling material layers 238-1, 238-2 have different etching selectivity, the top surface 238-1RT of the dielectric filling layer 238-1R may be lower than the top surface 236-1RT of the dielectric liner layer 236-1R, after performing the etching process. Furthermore, the etching process may form openings O3 between the semiconductor stack structures 220 in the location 10, and openings O4 between the mask patterns 216 in the location 20. The top surface 236-1RT of the dielectric liner 236-1R may be aligned with the interface between the first floating gate 206L and the second floating gate 206U (i.e., the top surface 206LT of the first floating gate 206L). Alternatively, the top surface 236-1RT of the dielectric liner 236-1R may be located below the interface between the first floating gate 206L and the second floating gate 206U (i.e., the top surface 206LT of the first floating gate 206L).

In some embodiments, the dielectric fill layer 238-1R may include a dielectric material, such as silicon oxide, silicon nitride, silicon oxynitride, phosphosilicate glass, borophosphosilicate glass, fluorinated silicate glass, undoped silica glass, organic silicate glass, SiOₓC_{y}, spin-on glass, tetraethyl orthosilicate, a low-k dielectric material, or a combination thereof. In some embodiments, the dielectric filling layer 238-1R, the dielectric liner 224R1′ and the dielectric filling layer 226R1′ of the isolation structure 230R1′, and the dielectric liner 224R2 and the dielectric filling layer 226R2 of the isolation structure 230R2 include the same material, such as silicon oxide.

In some embodiments, the etching process includes a selective etching process, and the etching selectivity of the etching process can be controlled so that the etching rate of the dielectric filling material layers 238-1, 238-2 (formed of silicon oxide) shown in FIGS. 4A and 4B is greater than the etching rate of the dielectric liner material layers 236-1, 236-2 (formed of silicon nitride).

It should be noted that the pattern density in the location 10 is higher than that in the location 20. Therefore, the etching processes shown in FIG. 5A and FIG. 5B have different etching rates in the locations 10 and 20. At this time, the dielectric liner material layer 236-1 of the isolation feature 240-1 and the dielectric liner material layer 236-2 of the isolation feature 240-2 shown in FIGS. 4A and 4B may be used as an etching stop layer for the above-mentioned etching process to control the degree of recess in the isolation features 240-1R and 240-2R in the locations 10 and 20 after performing the etching process. For example, the lowest point of the top surface 240-2RT (concave arc surface) of the isolation feature 240-2R in the location 20 will not be lower than the lowest point of the dielectric liner 236-1R. The method for forming the flash memory device 500 in accordance with some embodiments of the disclosure may prevent the above-mentioned patterning process from forming recesses in the isolation features having excessively large variations in depths in the locations (the locations 10 and 20) having different pattern densities in the array region by forming the isolation features 240-1 and 240-2 having a tri-layer structure including silicon oxide/silicon nitride/silicon oxide (ONO), thereby improving the word line disturb problem.

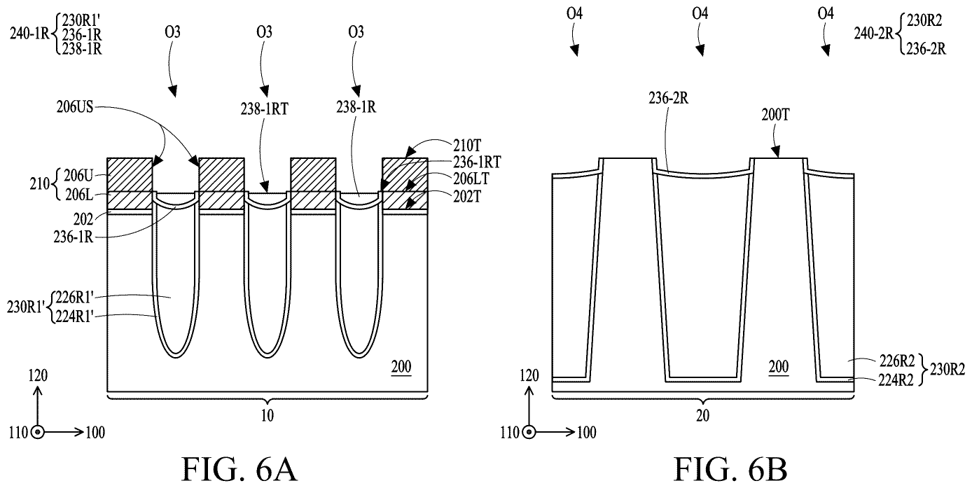

Next, as shown in FIG. 6A and FIG. 6B, multiple etching processes including dry etching and wet etching may be performed to remove the mask patterns 216 (including the oxide layer 212O and the nitride layer 212N) in the locations 10 and 20, thereby exposing the top surface 210T of the floating gate 210 in the location 10 and the top surface 200T of the substrate 200 in the location 20. The etching process may remove portions of the dielectric liner layers 236-1R, 236-2R and the dielectric filling layer 238-1R from the openings O3 and O4.

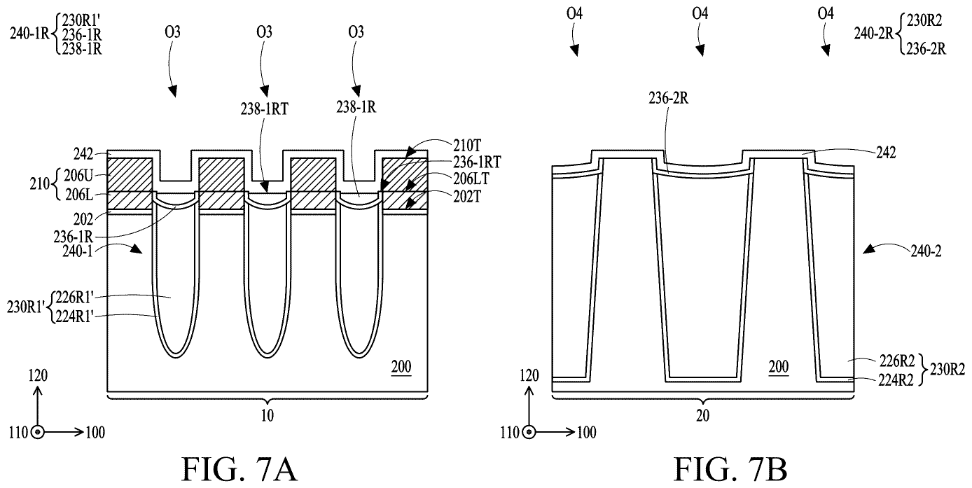

Next, as shown in FIGS. 7A and 7B, a deposition process may be performed to conformally form a gate dielectric layer 242 on the isolation features 240-1R, 240-2R and the floating gates 210. The gate dielectric layer 242 may cover the top surfaces of the isolation features 240-1R and may not fill the openings O3 between the floating gates 210. The gate dielectric layer 242 may cover the dielectric liners 236-2R of the isolation features 240-2R and may not fill the openings O4 in the substrate 200. In one embodiment, the gate dielectric layer 242 includes silicon oxide, silicon nitride, silicon oxynitride, or a tri-layer structure including silicon oxide/silicon nitride/silicon oxide (ONO).

Next, as shown in FIGS. 8A and 8B, a deposition process may be performed to form a control gate layer 246 on the gate dielectric layer 242. The control gate layer 246 fills the openings O3 between the floating gates 210 in the location 10 and the openings O4 in the substrate 200 in the location 20. In some embodiments, the control gate layer 246 includes polysilicon or another conductive material layer. After performing the aforementioned processes, the flash memory device 500 is formed.

As shown in FIG. 8A, the flash memory device 500 includes a substrate 200, a semiconductor stack structure 250, and a plurality of isolation features 240-1R. The semiconductor stack structure 250 is disposed on the substrate 200. The semiconductor stack structure 250 includes a tunneling dielectric layer 202 and a floating gate 210 (including a first floating gate 206L and a second floating gate 206U). The first floating gate 206L is disposed on the tunneling dielectric layer 202. The second floating gate 206U is disposed on the first floating gate 206L. The isolation features 240-1R are disposed in the substrate 200 adjacent to the semiconductor stack structure 250 and extends along the direction 120 to protrude from the substrate 200, so that the semiconductor stack structure 250 is sandwiched between the isolation features 240-1R. Each of the isolation features 240-1R includes a dielectric filling layer 226R1′, a dielectric liner 236-1R, and a dielectric filling layer 238-1R. The dielectric filling layer 226R1′ is located at the lower portion 240-1L of the isolation feature 240-1R. The dielectric liner 236-1R conformally covers the dielectric filling layer 226R1′. The dielectric filling layer 238-1R is located at the upper portion 240-1U of the isolation feature 240-1R, so that the dielectric liner 236-1R is sandwiched between the dielectric filling layer 226R1′ and the dielectric filling layer 238-1R. In some embodiments, the dielectric filling layer 226R1′ and the dielectric filling layer 238-1R are formed of a first material. In addition, the dielectric liner 236-1R is formed of a second material. The second material is different from the first material. In some embodiments, the first material includes an oxide and the second material includes a nitride.

In some embodiments, the top surface 236-1RT of the dielectric liner 236-1R is aligned with the interface between the first floating gate 206L and the second floating gate 206U (i.e., the top surface 206LT of the first floating gate 206L). Alternatively, the top surface 236-1RT of the dielectric liner 236-1R is located below the interface between the first floating gate 206L and the second floating gate 206U (i.e., the top surface 206LT of the first floating gate 206L). In other words, the top surface 236-1RT of the dielectric liner 236-1R is not higher than the interface between the first floating gate 206L and the second floating gate 206U (i.e., the top surface 206LT of the first floating gate 206L). In some embodiments, the top surface of the isolation feature 240-1R includes the top surface 236-1RT of the dielectric liner 236-1R and the top surface 238-1RT of the dielectric fill layer 238-1R.

In the isolation feature 240-1R, the interface between the dielectric filling layer 226R1′ and the dielectric liner 236-1R is a concave arc surface. The lowest point of the concave arc surface is located above the top surface 202T of the tunneling dielectric layer 202.

In the isolation feature 240-1R, the dielectric liner 236-1R covers the opposite side surfaces 206LS of the first floating gate 206L. The opposite side surfaces 206US of the second floating gate 206U may be exposed from the dielectric liner 236-1R.

In some embodiments, the isolation feature 240-1R may further include a dielectric liner 224R1′. The dielectric liner 224R1′ surrounds the dielectric filling layer 226R1′ and is adjacent to the side surface 202S of the tunneling dielectric layer 202 and the side surface 206LS of the first floating gate 206L. In some embodiments, the tunneling dielectric layer 202 and the first floating gate 206L may be separated from the dielectric liner 236-1R by the dielectric liner 224R1′. Alternatively, the dielectric liner 224R1′ and the dielectric liner 236-1R may be adjacent to different portions of the side surface 206LS of the first floating gate 206L. In some embodiments, the dielectric liner 224R1′ is formed of a first material, such as oxide.

The flash memory device 500 further includes a gate dielectric layer 242 and a control gate layer 246. The gate dielectric layer 242 is formed on the isolation feature 240-1R and the floating gate 210. The control gate layer 246 is formed on the gate dielectric layer 242. In some embodiments, the gate dielectric layer 242 is adjacent to the dielectric filling layer 238-1R and the dielectric liner 236-1R.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory device, comprising:
a substrate;
a semiconductor stack structure disposed on the substrate, wherein the semiconductor stack structure comprises:
a first floating gate; and
a second floating gate disposed on the first floating gate; and
isolation features disposed in the substrate and protruding from the substrate, so that the semiconductor stack structure is sandwiched between the isolation features, wherein each of the isolation features comprises:
a first dielectric filling layer located at a lower portion of the isolation feature;
a second dielectric liner conformally covering the first dielectric filling layer; and
a third dielectric filling layer located on an upper portion of the isolation feature, so that the second dielectric liner is sandwiched between the first dielectric filling layer and the third dielectric filling layer, wherein the first dielectric filling layer and the third dielectric filling layer are formed of a first material, and the second dielectric liner is formed of a second material, and the second material is different from the first material, and wherein a first top surface of each of the isolation features includes a third top surface of the third dielectric filling layer and a second top surface of the second dielectric liner.

2. The flash memory device as claimed in claim 1, wherein the second top surface of the second dielectric liner of each of the isolation features is aligned with a first interface between the first floating gate and the second floating gate, or is located below the first interface.

3. The flash memory device as claimed in claim 1, wherein the first material comprises an oxide and the second material comprises a nitride.

4. The flash memory device as claimed in claim 1, further comprising:
a tunneling dielectric layer sandwiched between the substrate and the semiconductor stack structure, wherein a second interface between the first dielectric filling layer and the second dielectric liner is a concave arc surface, and a lowest point of the concave arc surface is located above the tunneling dielectric layer.

5. The flash memory device as claimed in claim 1, wherein the second dielectric liner covers first side surfaces of the first floating gate.

6. The flash memory device as claimed in claim 1, wherein in each of the isolation features, a third top surface of the third dielectric filling layer is lower than a second top surface of the second dielectric liner.

7. The flash memory device of claim 4, wherein each of the isolation features further comprises:
a fourth dielectric liner surrounding the first dielectric filling layer and adjacent to third side surfaces of the tunneling dielectric layer and first side surfaces of the first floating gate, wherein the fourth dielectric liner is formed of the first material.

8. The flash memory device as claimed in claim 7, wherein the second dielectric liner and the fourth dielectric liner are adjacent to different portions of the first side surfaces of the first floating gate.

9. The flash memory device as claimed in claim 1, further comprising:
a gate dielectric layer formed on the isolation features and the floating gate; and
a control gate layer formed on the gate dielectric layer.

10. The flash memory device as claimed in claim 9, wherein the gate dielectric layer is adjacent to the third dielectric filling layer and the second dielectric liner.

11. A method for forming a flash memory device, comprising:
forming a semiconductor stack structure and isolation features on the substrate, wherein the isolation features protrude from the substrate, so that the semiconductor stack structure is sandwiched between the isolation features, wherein the semiconductor stack structure comprises:
a first floating gate; and
a second floating gate disposed on the first floating gate;
wherein the formation of each of the isolation features comprises:
forming a first dielectric filling layer in the substrate adjacent to the semiconductor stack structure, wherein a first top surface of the first dielectric filling layer is recessed from a second top surface of the semiconductor stack structure;
conformally forming a second dielectric liner material layer on the semiconductor stack structure and the first top surface of the first dielectric filling layer;
forming a third dielectric filling material layer on the second dielectric liner material layer; and
removing a portion of the second dielectric liner material layer and a portion of the third dielectric filling material layer to expose second side surfaces of the second floating gate, thereby forming a second dielectric liner and a third dielectric filling layer of each of the isolation features, wherein a first top surface of each of the isolation features includes a top surface of the third dielectric filling layer and a top surface of the second dielectric liner,
wherein the first dielectric filling layer and the third dielectric filling material layer are formed of a first material, the second dielectric liner material layer is formed of a second material, and the second material is different from the first material.

12. The method for forming a flash memory device as claimed in claim 11, wherein before forming the second dielectric liner material layer, the first top surface of the first dielectric filling layer is a concave arc surface, and a lowest point of the concave arc surface is located below a third top surface of the first floating gate.

13. The method for forming a flash memory device as claimed in claim 11, wherein the second dielectric liner material layer is adjacent to first side surfaces of the first floating gate.

14. The method for forming a flash memory device as claimed in claim 11, wherein a fourth top surface of the second dielectric liner material layer is aligned with a first interface between the first floating gate and the second floating gate, or located below the first interface.

15. The method for forming a flash memory device as claimed in claim 11, further comprising:
forming a tunneling dielectric layer on the substrate before forming the semiconductor stack structure; and
forming a fourth dielectric liner in the substrate adjacent to the semiconductor stack structure, wherein the fourth dielectric liner surrounds the first dielectric filling layer and is adjacent to third side surfaces of the tunneling dielectric layer and first side surfaces of the first floating gate, wherein the fourth dielectric liner is formed of the first material.

16. The method for forming a flash memory device as claimed in claim 11, further comprising:
recessing the first dielectric filling layer before forming the second dielectric liner material layer, so that the second side surfaces of the second floating gate are exposed.

17. The method for forming a flash memory device as claimed in claim 14, wherein the second dielectric liner material layer covers the fourth dielectric liner.

18. The method for forming a flash memory device as claimed in claim 11, wherein removing the portion of the second dielectric liner material layer and the portion of the third dielectric filling material layer comprises:
performing a planarization process to remove the second dielectric liner material layer and the third dielectric filling layer on the second top surface of the semiconductor stack structure; and
performing an etching process to remove a portion of the second dielectric liner material layer and a portion of the third dielectric filling layer on the first dielectric filling layer.

19. The method for forming a flash memory device as claimed in claim 11, further comprising:
forming a gate dielectric layer on the isolation features and the floating gate; and
forming a control gate layer on the gate dielectric layer.
